(19) United States
(12) Patent Application Publication
(10) Pub. No.: US 2020/0095498 A1
(43) Pub. Date: Mar. 26, 2020

(54) SEMICONDUCTING LIGHT EMITTING NANOPARTICLE

(71) Applicant: Merck Patent GmbH, Darmstadt (DE)

(72) Inventors: Itai LIEBERMAN, Dreieich (DE); Denis GLOZMAN, Modiin (IL); Artyom SEMYONOV, Rehovot (IL); Ehud SHAVIV, Modiin (IL); Christian-Hubertus KUECHENTHAL, Jerusalem (IL); Shany NEYSHTADT, Jerusalem (IL); Nathan GRUMBACH, Efrat (IL)

(73) Assignee: Merck Patent GmbH, Darmstadt (DE)

(21) Appl. No.: 16/498,530

(22) PCT Filed: Mar. 28, 2018
(86) PCT No.: PCT/EP2018/057886

§ 371 Date: Sep. 27, 2019

(30) Foreign Application Priority Data
Mar. 31, 2017 (EP) 17164127.7
Apr. 19, 2017 (EP) 17167142.3

(51) Int. Cl. C09K 11/02; C09K 11/88; C09K 11/08; H01L 33/06

(52) U.S. Cl. CPC C09K 11/025; H01L 33/06; C09K 11/0883; C09K 11/883

(57) ABSTRACT

The present invention relates to semiconducting light emitting nanoparticles, their preparation and use in devices.

### FIELD OF THE INVENTION

The present invention relates to a semiconducting light emitting nanoparticle; a process for fabricating a semiconducting light emitting nanoparticle; composition, formulation and use of a semiconducting light emitting nanoparticle, an optical medium; and an optical device.

### BACKGROUND ART

Semiconducting light emitting nanoparticle and several process for preparing a semiconducting light emitting nanoparticle are known in the prior art documents.

For example, as described in Chem. Mater., vol. 21, No. 4, 2009, J. Am. Chem. Soc. 2008, 130, 11588-11589 and J. Am. Chem. Soc. 2012, 134, 19701-19708, J. Phys. Chem. C, 2008, 112, 20190-20199, Appl. Phys Lett., 2012, 101, 073107, J. Phys. Chem. C, 2012, 116, 3944, Chem. Commun., 2009, 5214-5226, J. Phys. Chem. B, 2003, 107, 11346-11352, J. Am. Chem. Soc. 2007, 129(10), 2847.

### PATENT LITERATURE

### Non Patent Literature

1. Chem. Mater., vol. 21, No. 4, 2009
2. J. Am. Chem. Soc. 2008, 130, 11588-11589
3. J. Am. Chem. Soc. 2012, 134, 19701-19708
4. J. Phys. Chem. C, 2008, 112, 20190-20199
5. Appl. Phys Lett., 2012, 101, 073107
6. J. Phys. Chem. C, 2012, 116, 3944
7. Chem. Commun., 2009, 5214-5226
8. J. Phys. Chem. B, 2003, 107, 11346-11352
9. J. Am. Chem. Soc. 2007, 129(10), 2847

### SUMMARY OF THE INVENTION

However, the inventors newly have found that there are still one or more of considerable problems for which improvement is desired as listed below.
1. Novel semiconducting light emitting nanoparticle, which can show improved quantum yield, is desired.
2. Novel semiconducting light emitting nanoparticle, which can lead long term stable emission of the semiconducting light emitting nanoparticle, is required.
3. Novel semiconducting light emitting nanoparticle comprising a ligand, in which the attaching group can well cover the surface of the semiconducting light emitting nanoparticle, is also desired.
4. Simple fabrication process for making an optical medium comprising a semiconductor nanocrystal, is requested.
5. Novel process for preparing a semiconducting light emitting nanoparticle, which can show improved quantum yield, is desired.
6. Simple process for preparing a semiconducting light emitting nanoparticle, which can show improved quantum yield, is requested.

The inventors aimed to solve one or more of the problems indicated above 1 to 6.

Then, it was found a novel semiconducting light emitting nanoparticle comprising, essentially consisting of, or consisting of a core, one or more shell layers and an attaching group placed onto the outermost surface of the shell layers, wherein the attaching group is represented by following chemical formula (I),

M(O₂CR¹)₂(NR²R³R⁴)_{y} (I)

wherein y is 0, or 2, preferably y is 0,
M is Zn²⁺ or Cd²⁺, preferably Zn²⁺,
if y is 2, R¹ is a linear alkyl group having 1 to 25 carbon atoms, a branched alkyl group having 4 to 25 carbon atoms, a linear alkenyl group having 2 to 25 carbon atoms, or a branched alkenyl group having 4 to 25 carbon atoms, preferably R¹ is a linear alkyl group having 1 to 25 carbon atoms or a linear alkenyl group having 2 to 25 carbon atoms,
if y is 0, R¹ is a linear alkyl group having 1 to 15 carbon atoms, a branched alkyl group having 4 to 15 carbon atoms, a linear alkenyl group having 2 to 15 carbon atoms, or a branched alkenyl group having 4 to 15 carbon atoms, preferably R¹ is a linear alkyl group having 1 to 15 carbon atoms or a linear alkenyl group having 2 to 15 carbon atoms,
R², R³ and R⁴ are independently or dependently of each other, selected from the group consisting of a hydrogen atom, a linear alkyl group having 1 to 25 carbon atoms, a branched alkyl group having 4 to 25 carbon atoms, a linear alkenyl group having 2 to 25 carbon atoms, and a branched alkenyl group having 4 to 25 carbon atoms,
with the proviso that at least one of R², R³ and R⁴ is a linear alkyl group having 1 to 25 carbon atoms, a branched alkyl group having 4 to 25 carbon atoms, a linear alkenyl group having 2 to 25 carbon atoms, or a branched alkenyl group having 4 to 25 carbon atoms, preferably, R², R³ is a hydrogen atom and R⁴ is a linear alkyl group having 1 to 25 carbon atoms, a branched alkyl group having 4 to 25 carbon atoms, a linear alkenyl group having 2 to 25 carbon atoms, or a branched alkenyl group having 4 to 25 carbon atoms.

In another aspect, the invention relates to a novel semiconducting light emitting nanoparticle comprising, essentially consisting of, or consisting of a core, one or more shell layers, a 1^{st} attaching group and a 2^{nd} attaching group placed onto the outermost surface of the shell layers, wherein said 1^{st} attaching group is represented by following chemical formula (II), and said 2^{nd} attaching group is represented by following chemical formula (III),

[M(O₂CR⁵)⁻]⁺ (II)

O₂CR⁶⁻ (III)

wherein M is Zn²⁺ or Cd²⁺, preferably M is Zn²⁺,
R⁵ is a linear alkyl group having 1 to 15 carbon atoms, a branched alkyl group having 4 to 15 carbon atoms, a linear alkenyl group having 2 to 15 carbon atoms, or a branched alkenyl group having 4 to 15 carbon atoms, preferably R⁵ is a linear alkyl group having 1 to 15 carbon atoms or a linear alkenyl group having 2 to 15 carbon atoms, more preferably R⁵ is a linear alkyl group having 1 to 10 carbon atoms or a linear alkenyl group having 2 to 10 carbon atoms, even more preferably R⁵ is a linear alkyl group having 1 to 8 carbon atoms or a linear alkenyl group having 2 to 6 carbon atoms, further more preferably R⁵ is a linear alkyl group having 1 to 4 carbon atoms or a linear alkenyl group having 2 to 4 carbon atoms, the most preferably R⁵ is a linear alkyl group having 1 to 2 carbon atoms,
R⁶ is a linear alkyl group having 1 to 15 carbon atoms, a branched alkyl group having 4 to 15 carbon atoms, a linear alkenyl group having 2 to 15 carbon atoms, or a branched alkenyl group having 4 to 15 carbon atoms, preferably R⁶ is a linear alkyl group having 1 to 15 carbon atoms or a linear alkenyl group having 2 to 15 carbon atoms, more preferably R⁶ is a linear alkyl group having 1 to 10 carbon atoms or a linear alkenyl group having 2 to 10 carbon atoms, even more preferably R⁶ is a linear alkyl group having 1 to 8 carbon atoms or a linear alkenyl group having 2 to 6 carbon atoms, further more preferably R⁶ is a linear alkyl group having 1 to 4 carbon atoms or a linear alkenyl group having 2 to 4 carbon atoms, the most preferably R⁶ is a linear alkyl group having 1 to 2 carbon atoms.

In another aspect, the invention also relates to a process for fabricating a semiconducting light emitting nanoparticle, wherein the method comprises or consists of the following step (a),
(a) providing the attaching group represented by chemical formula (I) and a semiconducting light emitting nanoparticle comprising a core, one or more shell layers into a solvent to get a mixture.

In another aspect, the present invention further relates to a process for preparing a semiconducting light emitting nanoparticle, wherein the process comprises, or consists of following steps (a1) and (b) in this sequence,

(a1) preparing a semiconducting light emitting nanoparticle comprising a core, one or more shell layers and an attaching group placed onto the outermost surface of the shell layers, wherein the attaching group is represented by following chemical formula (V),

MYXZ (V)

wherein M is a divalent metal ion, preferably M is Zn²⁺, or Cd²⁺, more preferably it is Zn²⁺;
Y and X are, independently or differently of each other, selected from the group consisting of carboxylates, halogens, acetylacetonates, phosphates, phosphonates, sulfonates, sulfates, thiocarbamates, dithiocarbamates, thiolates, dithiolates and alkoxylates, preferably, Y and X are identical,
Z is (NR⁷R⁸R⁹)_{y}
wherein y is 0, or 2, preferably y is 0,
R⁷, R⁸ and R⁹ are independently or dependently of each other, selected from the group consisting of a hydrogen atom, a linear alkyl group having 1 to 25 carbon atoms, a branched alkyl group having 4 to 25 carbon atoms, a linear alkenyl group having 2 to 25 carbon atoms, and a branched alkenyl group having 4 to 25 carbon atoms,
with the proviso that at least one of R⁷, R⁸ and R⁹ is a linear alkyl group having 1 to 25 carbon atoms, a branched alkyl group having 4 to 25 carbon atoms, a linear alkenyl group having 2 to 25 carbon atoms, or a branched alkenyl group having 4 to 25 carbon atoms,
(b) Irradiating light with a peak light wavelength in the range from 300 nm to 650 nm to the semiconducting light emitting nanoparticle, with preferably being in the range from 320 nm to 520 nm, more preferably from 350 nm to 500 nm, even more preferably at 360 nm to 470 nm.

In another aspect, the invention relates to semiconducting light emitting nanoparticle obtainable or obtained from the process.

In another aspect, the invention relates to a composition comprising, essentially consisting of, or consisting of the semiconducting light emitting nanoparticle or obtained according to the process, and at least one additional material, preferably the additional material is selected from the group consisting of organic light emitting materials, inorganic light emitting materials, charge transporting materials, scattering particles, and matrix materials, preferably the matrix materials are optically transparent polymers.

In another aspect, the invention further relates to formulation comprising, essentially consisting of, or consisting of the semiconducting light emitting nanoparticle or the semiconductor light emitting nanoparticle obtained according to the process, or the composition, and at least one solvent, preferably the solvent is selected from one or more members of the group consisting of aromatic, halogenated and aliphatic hydrocarbons solvents, more preferably selected from one or more members of the group consisting of toluene, xylene, ethers, tetrahydrofuran, chloroform, dichloromethane and heptane.

In another aspect, the invention further relates to use of the semiconducting light emitting nanoparticle or obtained according to the process, or the composition, or the formulation in an electronic device, optical device or in a biomedical device.

In another aspect, the invention also relates to an optical medium comprising the semiconducting light emitting nanoparticle or obtained according to the process, or the composition.

In another aspect, the invention further relates to an optical device comprising the optical medium.

Further advantages of the present invention will become evident from the following detailed description.

### DESCRIPTION OF DRAWINGS

FIG. 1: shows a cross sectional view of a schematic of illumination setup used in the working example 1.

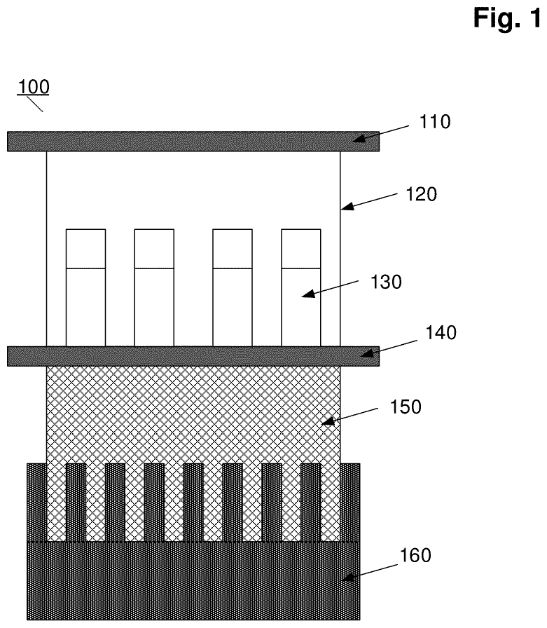

### LIST OF REFERENCE SIGNS IN FIG. 1

100. an illumination setup
110. a cover
120. a plastic cylinder
130. a sealed sample vial
140. Perspex®
150. LED
160. a heatsink

### DETAILED DESCRIPTION OF THE INVENTION

In one aspect of the present invention, said semiconducting light emitting nanoparticle comprising, essentially consisting of, or consisting of a core, one or more shell layers and an attaching group placed onto the outermost surface of the shell layers, wherein the attaching group is represented by following chemical formula (I),

M(O₂CR¹)₂(NR²R³R⁴)_{y} (I)

wherein y is 0, or 2, preferably y is 0,
M is Zn²⁺ or Cd²⁺, preferably Zn²⁺,
if y is 2, R¹ is a linear alkyl group having 1 to 25 carbon atoms, a branched alkyl group having 4 to 25 carbon atoms, a linear alkenyl group having 2 to 25 carbon atoms, or a branched alkenyl group having 4 to 25 carbon atoms, preferably R¹ is a linear alkyl group having 1 to 25 carbon atoms or a linear alkenyl group having 2 to 25 carbon atoms,
if y is 0, R¹ is a linear alkyl group having 1 to 15 carbon atoms, a branched alkyl group having 4 to 15 carbon atoms, a linear alkenyl group having 2 to 15 carbon atoms, or a branched alkenyl group having 4 to 15 carbon atoms, preferably R¹ is a linear alkyl group having 1 to 15 carbon atoms or a linear alkenyl group having 2 to 15 carbon atoms,
R², R³ and R⁴ are independently or dependently of each other, selected from the group consisting of a hydrogen atom, a linear alkyl group having 1 to 25 carbon atoms, a branched alkyl group having 4 to 25 carbon atoms, a linear alkenyl group having 2 to 25 carbon atoms, and a branched alkenyl group having 4 to 25 carbon atoms,
with the proviso that at least one of R², R³ and R⁴ is a linear alkyl group having 1 to 25 carbon atoms, a branched alkyl group having 4 to 25 carbon atoms, a linear alkenyl group having 2 to 25 carbon atoms, or a branched alkenyl group having 4 to 25 carbon atoms, preferably, R², R³ is a hydrogen atom and R⁴ is a linear alkyl group having 1 to 25 carbon atoms, a branched alkyl group having 4 to 25 carbon atoms, a linear alkenyl group having 2 to 25 carbon atoms, or a branched alkenyl group having 4 to 25 carbon atoms.

For examples, R¹, R², R³ and R⁴ are, independently or dependently of each other, can be selected from the groups in the following table 1.

TABLE 1
—CH₃

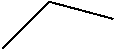

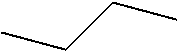

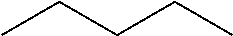

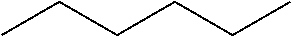

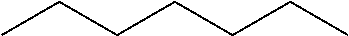

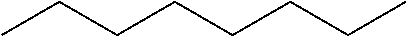

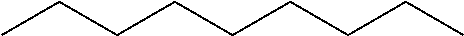

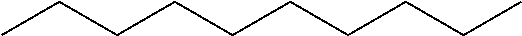

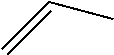

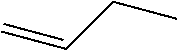

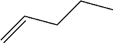

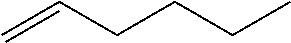

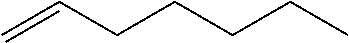

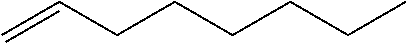

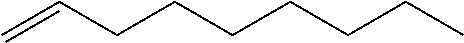

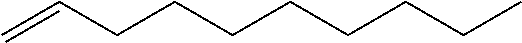

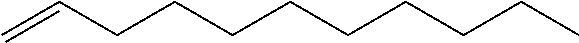

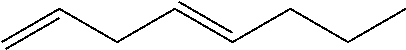

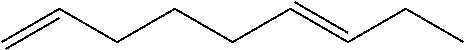

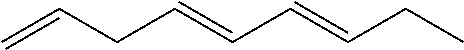

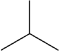

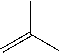

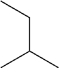

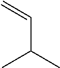

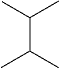

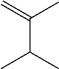

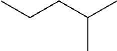

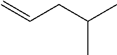

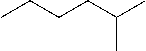

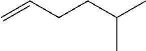

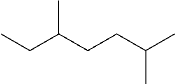

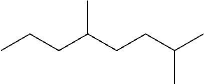

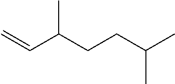

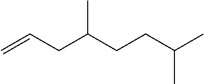

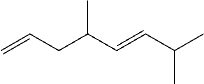

In some embodiments of the present invention, preferably, the attaching group is represented by following chemical formula (I′),

M(O₂CR¹)₂ (I′)

wherein R¹ is a linear alkyl group having 1 to 15 carbon atoms, preferably 1 to 10 carbon atoms, more preferably 1 to 8 carbon atoms, even more preferably 1 to 4 carbon atoms, further more preferably 1 to 2 carbon atoms, or an alkenyl group having 2 to 15 carbon atoms, preferably 2 to 10 carbon atoms, more preferably 2 to 6 carbon atoms, even more preferably 2 to 4 carbon atoms. The most preferably, the attaching group is Zn²⁺ (CH₃COO⁻)₂.

In another aspect of the present invention, a semiconducting light emitting nanoparticle comprising or consisting of a core, one or more shell layers, a 1^{st} attaching group and a 2^{nd} attaching group placed onto the outermost surface of the shell layers, wherein said 1^{st} attaching group is represented by following chemical formula (II), and said 2^{nd} attaching group is represented by following chemical formula (III),

[M(O₂CR⁵)⁻]⁺ (II)

O₂CR⁶⁻ (III)

wherein M is Zn²⁺ or Cd²⁺, preferably M is Zn²⁺,
R⁵ is a linear alkyl group having 1 to 15 carbon atoms, a branched alkyl group having 4 to 15 carbon atoms, a linear alkenyl group having 2 to 15 carbon atoms, or a branched alkenyl group having 4 to 15 carbon atoms, preferably R⁵ is a linear alkyl group having 1 to 15 carbon atoms or a linear alkenyl group having 2 to 15 carbon atoms, more preferably R⁵ is a linear alkyl group having 1 to 10 carbon atoms or a linear alkenyl group having 2 to 10 carbon atoms, even more preferably R⁵ is a linear alkyl group having 1 to 8 carbon atoms or a linear alkenyl group having 2 to 6 carbon atoms, further more preferably R⁵ is a linear alkyl group having 1 to 4 carbon atoms or a linear alkenyl group having 2 to 4 carbon atoms, the most preferably R⁵ is a linear alkyl group having 1 to 2 carbon atoms,
R⁶ is a linear alkyl group having 1 to 15 carbon atoms, a branched alkyl group having 4 to 15 carbon atoms, a linear alkenyl group having 2 to 15 carbon atoms, or a branched alkenyl group having 4 to 15 carbon atoms, preferably R⁶ is a linear alkyl group having 1 to 15 carbon atoms or a linear alkenyl group having 2 to 15 carbon atoms, more preferably R⁶ is a linear alkyl group having 1 to 10 carbon atoms or a linear alkenyl group having 2 to 10 carbon atoms, even more preferably R⁶ is a linear alkyl group having 1 to 8 carbon atoms or a linear alkenyl group having 2 to 6 carbon atoms, further more preferably R⁶ is a linear alkyl group having 1 to 4 carbon atoms or a linear alkenyl group having 2 to 4 carbon atoms, the most preferably R⁶ is a linear alkyl group having 1 to 2 carbon atoms.

For example, R⁵ and R⁶ are independently or dependently of each other, can be selected from the groups mentioned in the table 1 above.

Semiconducting Light Emitting Nanoparticle

According to the present invention, as an inorganic part of the semiconducting light emitting nanoparticle, a wide variety of publically known semiconducting light emitting nanoparticles can be used as desired.

A type of shape of the semiconducting light emitting nanoparticle of the present invention is not particularly limited.

Any type of semiconducting light emitting nanoparticles, for examples, spherical shaped, elongated shaped, star shaped, polyhedron shaped semiconducting light emitting nanoparticles, can be used.

In some embodiments of the present invention, said one or more shell layers of the semiconducting light emitting nanoparticle is a single shell layer, double shell layers, or multishell layers having more than two shell layers, preferably, it is a double shell layers.

According to the present invention, the term “shell layer” means the structure covering fully or partially said core. Preferably, said one or more shell layers fully covers said core. The term “core” and “shell” are well known in the art and typically used in the field of quantum materials, such as U.S. Pat. No. 8,221,651 B2.

According to the present invention, the term “nano” means the size in between 0.1 nm and 999 nm, preferably, it is from 0.1 nm to 150 nm.

In a preferred embodiment of the present invention, the semiconducting light emitting nanoparticle of the present invention is a quantum sized material.

According to the present invention, the term “quantum sized” means the size of the semiconductor material itself without ligands or another surface modification, which can show the quantum confinement effect, like described in, for example, ISBN:978-3-662-44822-9.

Generally, it is said that the quantum sized materials can emit tunable, sharp and vivid colored light due to “quantum confinement” effect.

In some embodiments of the invention, the size of the overall structures of the quantum sized material, is from 1 nm to 100 nm, more preferably, it is from 1 nm to 30 nm, even more preferably, it is from 5 nm to 15 nm.

According to the present invention, said core of the semiconducting light emitting nanoparticle can be varied.

For example, CdS, CdSe, CdTe, ZnS, ZnSe, ZnSeS, ZnTe, ZnO, GaAs, GaP, GaSb, HgS, HgSe, HgSe, HgTe, InAs, InP, InPS, InPZnS, InPZn, InPGa, InSb, AlAs, AlP, AlSb, Cu₂S, Cu₂Se, CulnS2, CulnSe₂, Cu₂(ZnSn)S₄, Cu₂(InGa)S₄, TiO₂ alloys and a combination of any of these can be used.

In a preferred embodiment of the present invention, said core of the semiconducting light emitting nanoparticle comprises one or more of group 13 elements of the periodic table and one or more of group 15 elements of the periodic table. For example, GaAs, GaP, GaSb, InAs, InP, InPS, InPZnS, InPZn, InPGa, InSb, AlAs, AlP, AlSb, CulnS2, CulnSe₂, Cu₂(InGa)S₄, and a combination of any of these.

Even more preferably, the core comprises In and P atoms. For example, InP, InPS, InPZnS, InPZn, InPGa.

In some embodiments of the present invention, said at least one of the shell layers comprises a 1^{st} element of group 12, 13 or 14 of the periodic table and a 2^{nd} element of group 15 or 16 of the periodic table, preferably, all shall layers comprises a 1^{st} element of group 12, 13 or 14 of the periodic table and a 2^{nd} element of group 15 or 16 of the periodic table.

In a preferred embodiment of the present invention, at least one of the shell layers comprises a 1^{st} element of group 12 of the periodic table and a 2^{nd} element of group 16 of the periodic table. For examples, CdS, CdZnS, ZnS, ZnSe, ZnSSe, ZnSSeTe, CdS/ZnS, ZnSe/ZnS, ZnS/ZnSe shell layers can be used. Preferably, all shall layers comprises a 1^{st} element of group 12 of the periodic table and a 2^{nd} element of group 16 of the periodic table.

More preferably, at least one shell layer is represented by following formula (IV),

ZnSₓSe_{y}Te_{z}, (IV)

wherein 0≤x≤1, 0≤y≤1, 0≤z≤1, and x+y+z=1, with even more preferably being of 0≤x≤1, 0≤y≤1, z=0, and x+y=1.

For examples, ZnS, ZnSe, ZnSeS, ZnSeSTe, CdS/ZnS, ZnSe/ZnS, ZnS/ZnSe shell layers can be used preferably.

Preferably, all shell layers are represented by formula (IV).

For example, as a semiconducting light emitting nanoparticle for green and/or red emission use, CdSe/CdS, CdSeS/CdZnS, CdSeS/CdS/ZnS, ZnSe/CdS, CdSe/ZnS, InP/ZnS, InP/ZnSe, InP/ZnSe/ZnS, InP/ZnS/ZnSe, InPZn/ZnS, InPZn/ZnSe/ZnS, InPZn/ZnS/ZnSe, ZnSe/CdS, ZnSe/ZnS semiconducting light emitting nanoparticle or combination of any of these, can be used.

More preferably, it is InP/ZnS, InP/ZnSe, InP/ZnSe/ZnS, InP/ZnS/ZnSe, InPZn/ZnS, InPZn/ZnSe/ZnS, InPZn/ZnS/ZnSe can be used.

In a preferred embodiment of the present invention, said shell layers of the semiconducting light emitting nanoparticle are double shell layers.

Said semiconducting light emitting nanoparticles are publically available, for example, from Sigma-Aldrich and/or described in, for example, ACS Nano, 2016, 10 (6), pp 5769-5781, Chem. Moter. 2015, 27, 4893-4898, and the international patent application laid-open No. WO2010/095140A.

Additional Ligand

In some embodiments of the present invention, optionally, the semiconducting light emitting nanoparticle can comprise a different type of surface attaching group in addition to the attaching group represented by the formula (I), (I′), (II), (III).

Thus, in some embodiments of the present invention, the outermost surface of the shell layers of the semiconducting light emitting nanoparticle can be over coated with different type of surface ligands together with the attaching group represented by the formula (I), (I′), (II), (III), if desired.

In case one or two of said another attaching group attached onto the outer most surface of the shell layer(s) of the semiconducting light emitting nanoparticle. In some embodiment of the present invention, the amount of the attaching group represented by the formula (I), (I′), and/or (II) and (III), is in the range from 30 wt % to 99.9 wt % of the total ligands attached onto the outermost surface of the shell layer(s).

Without wishing to be bound by theory it is believed that such a surface ligands may lead to disperse the nanosized fluorescent material in a solvent more easily.

The surface ligands in common use include phosphines and phosphine oxides such as Trioctylphosphine oxide (TOPO), Trioctylphosphine (TOP), and Tributylphosphine (TBP); phosphonic acids such as Dodecylphosphonic acid (DDPA), Tridecylphosphonic acid (TDPA), Octadecylphosphonic acid (ODPA), and Hexylphosphonic acid (HPA); amines such as Oleylamine, Dedecyl amine (DDA), Tetradecyl amine (TDA), Hexadecyl amine (HDA), and Octadecyl amine (ODA), Oleylamine (OLA), 1-Octadecene (ODE), thiols such as hexadecane thiol and hexane thiol; carboxylic acids such as oleic acid, stearic acid, myristic acid; acetic acid and a combination of any of these.

Examples of surface ligands have been described in, for example, the laid-open international patent application No. WO 2012/059931A.

Process

In another aspect, the invention also relates to a process for fabricating a semiconducting light emitting nanoparticle, wherein the method comprises or consists of the following step (a),
(a) providing the attaching group represented by chemical formula (I) and a semiconducting light emitting nanoparticle comprising a core, one or more shell layers into a solvent to get a mixture.

Preferably, said step (a) is carried out under an inert condition such as N2 atmosphere.

In a preferred embodiment of the present invention, step (a) is carried out at the temperature in the range from 60° C. to 0° C., more preferably at room temperature.

Preferably, in step (a), the attaching group represented by chemical formula (I) and a semiconducting light emitting nanoparticle are stirred for 1 sec or more. More preferably, 30 sec or more, even more preferably, the stirring time in step (a) is in the range from 1 min to 100 hours.

In some embodiments of the present invention, as the solvent for step (a), for example, toluene, hexane, chloroform, ethyl acetate, benzene, xylene, ethers, tetrahydrofuran, dichloromethane and heptane and a mixture of thereof, can be used preferably.

In another aspect of the present invention, said process for preparing a semiconducting light emitting nanoparticle comprises or consists of following steps (a′) and (b) in this sequence,

(a′) preparing a semiconducting light emitting nanoparticle comprising a core, one or more shell layers and an attaching group placed onto the outermost surface of the shell layers, wherein the attaching group is represented by following chemical formula (V),

MYXZ (V)

wherein M is a divalent metal ion, preferably M is Zn²⁺, Cd²⁺, more preferably it is Zn²⁺;
Y and X are, independently or differently of each other, selected from the group consisting of carboxylates, halogens, acetylacetonates, phosphates, phosphonates, sulfonates, sulfates, thiocarbamates, dithiocarbamates, thiolates, dithiolates and alkoxylates, preferably, Y and X are identical,
Z is (NR⁷R⁸R⁹)_{y}
wherein y is 0, or 2, preferably y is 0,
R⁷, R⁸ and R⁹ are independently or dependently of each other, selected from the group consisting of a hydrogen atom, a linear alkyl group having 1 to 25 carbon atoms, a branched alkyl group having 4 to 25 carbon atoms, a linear alkenyl group having 2 to 25 carbon atoms, and a branched alkenyl group having 4 to 25 carbon atoms,
with the proviso that at least one of R⁷, R⁸ and R⁹ is a linear alkyl group having 1 to 25 carbon atoms, a branched alkyl group having 4 to 25 carbon atoms, a linear alkenyl group having 2 to 25 carbon atoms, or a branched alkenyl group having 4 to 25 carbon atoms,
(b) irradiating light with a peak light wavelength in the range from 300 nm to 650 nm to the semiconducting light emitting nanoparticle, with preferably being in the range from 320 nm to 520 nm, more preferably from 350 nm to 500 nm, even more preferably at 360 nm to 470 nm.

For examples, R⁷, R⁸ and R⁹ are, independently or dependently of each other, can be selected from the groups in the following table 2.

TABLE 2
—CH₃

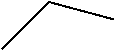

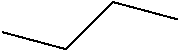

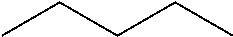

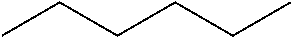

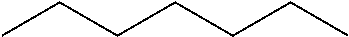

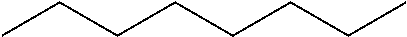

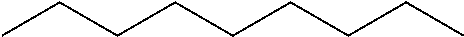

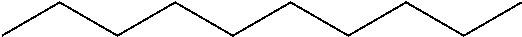

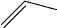

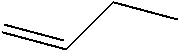

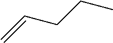

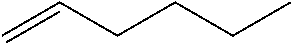

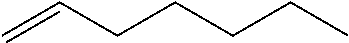

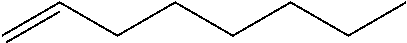

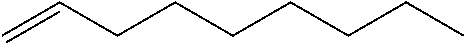

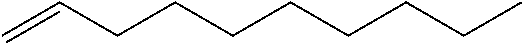

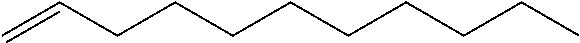

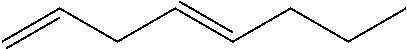

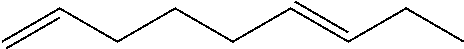

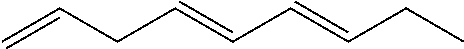

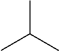

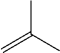

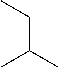

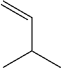

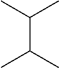

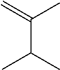

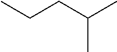

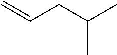

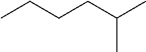

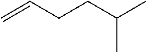

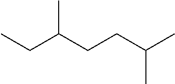

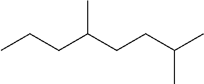

In a preferred embodiment of the present invention, R⁷, R⁸ and R⁹ are, independently or dependently of each other, can be selected from the groups in the following table 3.

TABLE 3

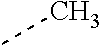

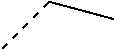

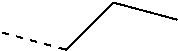

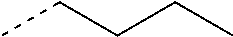

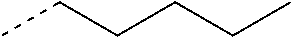

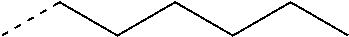

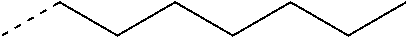

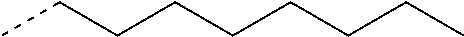

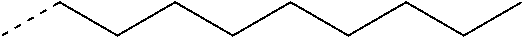

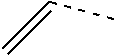

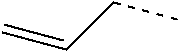

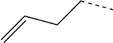

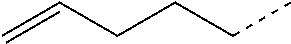

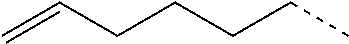

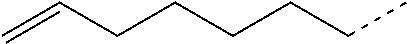

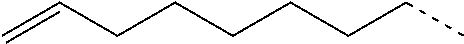

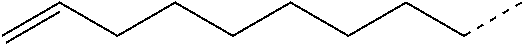

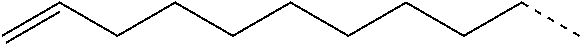

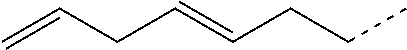

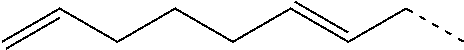

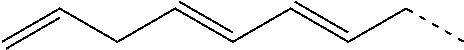

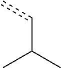

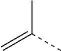

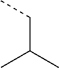

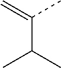

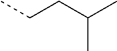

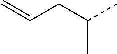

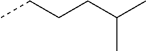

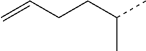

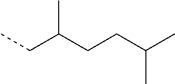

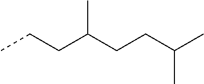

wherein the dotted line indicates a connecting point.

In a preferred embodiment of the present invention, a light source for light irradiation in step (b) is selected from one or more of artificial light sources, preferably selected from a light emitting diode, an organic light emitting diode, a cold cathode fluorescent lamp, or a laser device.

In some embodiments of the present invention, Y and X of the attaching group selected from carboxylates, halogens, acetylacetonates, phosphates, phosphonates, sulfonates, sulfates, thiocarbamates, dithiocarbamates, thiolates, dithiolates and alkoxylates, can comprise an aliphatic chain containing an aryl or hetero-aryl group.

In some embodiments, said aliphatic chain is a hydrocarbon chain which may comprise at least one double bond, one triple bond, or at least one double bond and one triple bond.

In some embodiments, said aryl group is a substituted or unsubstituted cyclic aromatic group.

In some embodiments, said aryl group includes phenyl, benzyl, naphthyl, tolyl, anthracyl, nitrophenyl, or halophenyl.

In some embodiments of the present invention, preferably, the attaching group is a carboxylate represented by following chemical formula (VI),

[M(O₂CR¹⁰)(O₂CR¹¹)] (VI)

wherein M is Zn²⁺ or Cd²⁺, preferably M is Zn²⁺,
wherein R¹⁰ is a linear alkyl group having 1 to 25 carbon atoms, a branched alkyl group having 4 to 25 carbon atoms, a linear alkenyl group having 2 to 25 carbon atoms, or a branched alkenyl group having 4 to 25 carbon atoms, preferably R¹⁰ is a linear alkyl group having 1 to 25 carbon atoms, or a linear alkenyl group having 2 to 25 carbon atoms, more preferably, R¹⁰ is a linear alkyl group having 1 to 20 carbon atoms, or a linear alkenyl group having 2 to 20 carbon atoms,
R¹¹ is a linear alkyl group having 1 to 25 carbon atoms, a branched alkyl group having 4 to 25 carbon atoms, a linear alkenyl group having 2 to 25 carbon atoms, or a branched alkenyl group having 4 to 25 carbon atoms, preferably R¹¹ is a linear alkyl group having 1 to 25 carbon atoms, or a linear alkenyl group having 2 to 25 carbon atoms, more preferably, R¹¹ is a linear alkyl group having 1 to 20 carbon atoms, or a linear alkenyl group having 2 to 20 carbon atoms.

For example, R¹⁰ and R¹¹ are independently or dependently of each other, can be selected from the groups mentioned in the table 1 above.

In some embodiment of the present invention, the process further comprises following steps (c) after step (a) and before step (b),
(c) mixing the semiconducting light emitting nanoparticle, and a solvent to get a mixture, preferably the solvent is selected from the group consisting of toluene, xylene, ethers, tetrahydrofuran, chloroform, dichloromethane and heptane.

In some embodiments in the present invention, optionally, one or more of said attaching groups represented by chemical formula (I) or (II) can be additionally mixed in step (c) with the semiconducting light emitting nanoparticle, and the solvent to get the mixture for step (b).

Preferably, the mixture obtained in step (c) is sealed in a transparent container, such as a vial.

In a preferred embodiment of the present invention, step (a′), (b) and/or (c) are carried out in an inert condition, such as N₂ atmosphere.

More preferably, all steps (a′), (b) and optionally step (c) are carried out in said inert condition.

In some embodiments of the present invention, the irradiation is step (b) is in the range from 0.025 to 1 watt/cm², preferably it is in the range from 0.05 to 0.5 watt/cm².

In some embodiments of the present invention, preferably, the total amount of photons absorbed by the semiconducting light emitting nanoparticle is in the range from 10²¹ to 10²³ photons/cm², more preferably from 7×10²¹ to 7×10²² photons/cm².

The total number of absorbed photons (per cm²) at the defined wavelength is calculated according to the following equation:

$$Absorbed photons = \frac{I}{hc / λ} * t * ( 1 - {10}^{- OD} )$$

I=irradiation intensity [Watt/cm²]
h=Planck constant (according to the International System of Units)
c=speed of light (according to the International System of Units)
λ=wavelength [m]
t=time [sec]
OD=absorption (based on absorption spectra measured in a spectrometer).

In some embodiments of the present invention, the step (b) is carried out at the temperature below 70° C., preferably in the range from 60° C. to 0° C., more preferably in the range from 50° C. to 20° C.

In another aspect, the invention relates to semiconducting light emitting nanoparticle obtainable or obtained from the process.

Composition

In another aspect, the present invention further relates a composition comprising or consisting of the semiconducting light emitting nanoparticle or obtained according to the process,

and at least one additional material, preferably the additional material is selected from the group consisting of organic light emitting materials, inorganic light emitting materials, charge transporting materials, scattering particles, and matrix materials, preferably the matrix materials are optically transparent polymers.

In a preferred embodiment of the present invention, the additional material is a matrix material.

Matrix Material

According to the present invention, a wide variety of publically known transparent matrix materials suitable for optical devices can be used preferably.

According to the present invention, the term “transparent” means at least around 60% of incident light transmit at the thickness used in an optical medium and at a wavelength or a range of wavelength used during operation of an optical medium. Preferably, it is over 70%, more preferably, over 75%, the most preferably, it is over 80%.

In some embodiments of the present invention, the transparent matrix material can be a transparent polymer.

According to the present invention the term “polymer” means a material having a repeating unit and having the weight average molecular weight (Mw) 1000 or more.

In some embodiments of the present invention, the glass transition temperature (Tg) of the transparent polymer is 70° C. or more and 250° C. or less.

Tg can be measured based on changes in the heat capacity observed in Differential scanning colorimetry like described in http://pslc.ws/macrog/dsc.htm; Rickey J Seyler, Assignment of the Glass Transition, ASTM publication code number (PCN) 04-012490-50.

For examples, as the transparent polymer for the transparent matrix material, poly(meth)acrylates, epoxys, polyurethanes, polysiloxanes, can be used preferably.

In a preferred embodiment of the present invention, the weight average molecular weight (Mw) of the polymer as the transparent matrix material is in the range from 1,000 to 300,000 g/mol, more preferably it is from 10,000 to 250,000 g/mol.

Formulation

In another aspect, the present invention further more relates to formulation comprising or consisting of the semiconducting light emitting nanoparticle or obtained according to the process, or the composition,

and at least one solvent, preferably the solvent is selected from one or more members of the group consisting of aromatic, halogenated and aliphatic hydrocarbons solvents, more preferably selected from one or more members of the group consisting of toluene, xylene, ethers, tetrahydrofuran, chloroform, dichloromethane and heptane.

The amount of the solvent in the formulation can be freely controlled according to the method of coating the composition. For example, if the composition is to be spray-coated, it can contain the solvent in an amount of 90 wt. % or more. Further, if a slit-coating method, which is often adopted in coating a large substrate, is to be carried out, the content of the solvent is normally 60 wt. % or more, preferably 70 wt. % or more.

In another aspect, the present invention also relates to use of the semiconducting light emitting nanoparticle, the mixture, or the formulation, in an electronic device, optical device or in a biomedical device.

Use

In another aspect, the invention further relates to use of the semiconducting light emitting nanoparticle or obtained according to the process, or the composition, or the formulation in an electronic device, optical device or in a biomedical device.

Optical Medium

In another aspect, the present invention further relates to an optical medium comprising the semiconducting light emitting nanoparticle or obtained according to the process, or the composition.

In some embodiments of the present invention, the optical medium can be an optical film, for example, a color filter, color conversion film, remote phosphor tape, or another film or filter.

Optical Device

In another aspect, the invention further relates to an optical device comprising the optical medium.

In some embodiments of the present invention, the optical device can be a liquid crystal display, Organic Light Emitting Diode (OLED), backlight unit for display, Light Emitting Diode (LED), Micro Electro Mechanical Systems (here in after “MEMS”), electro wetting display, or an electrophoretic display, a lighting device, and/or a solar cell.

### Effect of the Invention

The present invention provides,

1. a novel semiconducting light emitting nanoparticle, which can show improved quantum yield,
2. a novel semiconducting light emitting nanoparticle, which can lead long term stable emission of the semiconducting light emitting nanoparticle,
3. a novel semiconducting light emitting nanoparticle comprising a ligand, in which the attaching group can well cover the surface of the semiconducting light emitting nanoparticle,
4. a simple fabrication process for making an optical medium comprising a semiconductor nanocrystal,
5. novel process for preparing a semiconducting light emitting nanoparticle, which can show improved quantum yield,
6. simple process for preparing a semiconducting light emitting nanoparticle, which can show improved quantum yield.

### Definition of Terms

The term “semiconductor” means a material that has electrical conductivity to a degree between that of a conductor (such as copper) and that of an insulator (such as glass) at room temperature. Preferably, a semiconductor is a material whose electrical conductivity increases with the temperature.

The term “nanosized” means the size in between 0.1 nm and 999 nm, preferably 1 nm to 150 nm, more preferably 3 nm to 100 nm.

The term “emission” means the emission of electromagnetic waves by electron transitions in atoms and molecules.

The working examples 1-9 below provide descriptions of the present invention, as well as an in detail description of their fabrication.

### WORKING EXAMPLES

### Working Example 1

10 mg of pure Zinc acetate powders are added into 1 mL solution of InP/ZnSe containing 30 mg/mL quantum materials (prepared in a similar way to Mickael D. Tessier et al, Chem. Mater. 2015, 27, pp 4893-4898) in toluene. Then, the solution is stirred for 18 hours under inert atmosphere.

### Working Example 2

1 mL solution of InP/ZnSe containing 30 mg/mL quantum materials (according to Mickael D. Tessier et al, Chem. Mater. 2015, 27, pp 4893-4898) in toluene is cleaned in two cycles, using Toluene and ethanol mixed solvent giving 30 mg of pure quantum materials with 17 wt % of ligands.

Then, the solid content is dissolved in 1 mL of toluene, and 10 mg of pure Zinc acetate powders are added to the obtained solution and it is left for 18 hours stirring.

### Working Example 3

10 mg of pure Zinc undecylenate is added into 1 mL solution of InP/ZnSe containing 30 mg/mL quantum materials (according to Mickael D. Tessier et al, Chem. Mater. 2015, 27, pp 4893-4898) in toluene. Then, the solution is stirred for 18 hours under inert atmosphere.

Then the obtained solution is cleaned in two cycles, using Toluene and ethanol mixed solvent giving 30 mg of pure quantum materials with 40 wt % of ligands.

### Working Example 4

1 mL solution of InP/ZnSe containing 30 mg/mL quantum materials in toluene is prepared as described in working example 1, except for ZnO powders and acetic acid are added instead of adding Zinc acetate powders.

### Comparative Example 1

1 mL solution of InP/ZnSe containing 30 mg/mL quantum materials (according to Mickael D. Tessier et al, Chem. Mater. 2015, 27, pp 4893-4898) in toluene is prepared.

### Comparative Example 2

1 mL solution of InP/ZnSe containing 30 mg/mL quantum materials in toluene is prepared as described in working example 2 except for Zinc acetate powders are not added.

### Comparative Example 3

1 mL solution of InP/ZnSe containing 30 mg/mL quantum materials (according to Mickael D. Tessier et al, Chem. Mater. 2015, 27, pp 4893-4898) in toluene is prepared. And 60 mg of oleic acid is added into the solution. Then, the solution is stirred for 18 hours under inert atmosphere.

### Comparative Example 4

1 mL solution of InP/ZnSe containing 30 mg/mL quantum materials (according to Mickael D. Tessier et al, Chem. Mater. 2015, 27, pp 4893-4898) in toluene is prepared. And 60 mg of myristic acid is added into the solution. Then, the solution is stirred for 18 hours under inert atmosphere.

### Working Example 5: Measurements of Relative Quantum Yield (QY) Value of the Samples

The QY of solutions is measured in Hamamatsu Quantaurus absolute PL quantum yield spectrometer model c11347-11).

Table 4 shows the measurement results of the samples.

TABLE 4

| Examples | Quantum Yield (QY) |
|---|---|
| Comparative example 1 | 0.25 |
| Comparative example 2 | 0.30 |
| Comparative example 3 | 0.1 |
| Comparative example 4 | 0.05 |
| Working example 1 | 0.45 |
| Working example 2 | 0.45 |
| Working example 3 | 0.45 |
| Working example 4 | 0.51 |

The nanosized light emitting materials obtained in working examples 1, 2, 3, and 4 show better Quantum Yield.

### Working Example 6: Illumination Set Up

A lighting setup built with Philips Fortimo 3000 Im 34 W 4000K LED downlight module (with it is phosphor disc removed). A 1.9 nm thick Perspex Pane® is placed on top of this.

The distance between the LEDs and the Perspex Pane® is 31.2 mm. the 20 ml sealed sample vials are placed on the Perspex Pane® inside a plastic cylinder, diameter 68 mm height 100 mm. Then the cylinder is closed with a cardboard top as described in FIG. 1.

Photoenhancement system: The vials with the solution of QDs are placed on the Perspex plate of the setup described above and illuminated from below. To prevent the solution from extensive heating and evaporation of the solvent, the vials are placed in the water bath (a glass beaker with water).

The peak wavelength of the illumination is 455 nm. The irradiance at 450 nm is measured by an Ophir Nova II® and PD300-UV photodetector and measured to be 300 mW/cm².

### Comparative Example 5

InP/ZnSe QDs (prepared in a similar way to Mickael D. Tessier et al, Chem. Mater. 2015, 27, p 4893-4898) with QY of 28% are purified from access ligands using toluene/Ethanol as solvent/antisolvent. The sample is illuminated for 40 hours (see working example 1). The Quantum Yield (QY) is measured for this sample and compared to the same sample which is not illuminated. The QY of each sample solution is measured in Hamamatsu Quantaurus absolute PL quantum yield spectrometer (model c11347-11). The concentration of each sample solution is tuned to reach absorption of 60-80% in the measurement system.

### Comparative Example 6

20 mg of myristic acid (purchased from Sigma Aldrich) is added to 30 mg of the purified QDs (15% wt) dissolved in 1 ml toluene under inert conditions. The illumination is performed for 40 hours (see working example 1). The Quantum Yield is measured for this sample and compared to the same sample which is not illuminated. The QY of each sample is measured in Hamamatsu Quantaurus absolute PL quantum yield spectrometer (model c11347-11). The concentration of each sample solution is tuned to reach absorption of 60-80% in the measurement system.

### Comparative Example 7

Same as comparative example 5, except that oleic acid (from Sigma Aldrich) is added to the purified QDs.

### Working Example 7

Same as comparative example 5, except that Zn-stearate (from Sigma Aldrich) is added to the purified QDs.

### Working Example 8

Same as comparative example 5, except that Zn-oleate (purchased from American elements) is added to the purified QDs.

### Working Example 9

Same as comparative example 5, except that Zn-acetate (purchased from American elements) is added to the purified QDs.

Table 5 shows the measurement results of the samples.

TABLE 5

Quantum yield (%)

| Examples | Non-illuminated | Illuminated |
|---|---|---|
| Comparative example 5 | 8 | 25 |
| Comparative example 6 | 4 | 27 |
| Comparative example 7 | 6 | 27 |
| Working example 7 | 20 | 50 |
| Working example 8 | 11 | 48 |
| Working example 9 | 33 | 45 |

As it can be seen in the table 5, the working examples show more than 40% quantum yield and it is in sharp contrast to the comparative examples. The comparative examples show below 30% quantum yield even though it is illuminated.

1. A semiconducting light emitting nanoparticle comprising or consisting of a core, one or more shell layers and an attaching group placed onto the outermost surface of the shell layers, wherein the attaching group is represented by following chemical formula (I),
M(O₂CR¹)₂(NR²R³R⁴)_{y} (I)
wherein y is 0, or 2, preferably y is 0,
M is Zn²⁺ or Cd²⁺, preferably Zn²⁺,
if y is 2, R¹ is a linear alkyl group having 1 to 25 carbon atoms, a branched alkyl group having 4 to 25 carbon atoms, a linear alkenyl group having 2 to 25 carbon atoms, or a branched alkenyl group having 4 to 25 carbon atoms, preferably R¹ is a linear alkyl group having 1 to 25 carbon atoms or a linear alkenyl group having 2 to 25 carbon atoms,
if y is 0, R¹ is a linear alkyl group having 1 to 15 carbon atoms, a branched alkyl group having 4 to 15 carbon atoms, a linear alkenyl group having 2 to 15 carbon atoms, or a branched alkenyl group having 4 to 15 carbon atoms, preferably R¹ is a linear alkyl group having 1 to 15 carbon atoms or a linear alkenyl group having 2 to 15 carbon atoms,
R², R³ and R⁴ are independently or dependently of each other, selected from the group consisting of a hydrogen atom, a linear alkyl group having 1 to 25 carbon atoms, a branched alkyl group having 4 to 25 carbon atoms, a linear alkenyl group having 2 to 25 carbon atoms, and a branched alkenyl group having 4 to 25 carbon atoms,
with the proviso that at least one of R², R³ and R⁴ is a linear alkyl group having 1 to 25 carbon atoms, a branched alkyl group having 4 to 25 carbon atoms, a linear alkenyl group having 2 to 25 carbon atoms, or a branched alkenyl group having 4 to 25 carbon atoms, preferably, R², R³ is a hydrogen atom and R⁴ is a linear alkyl group having 1 to 25 carbon atoms, a branched alkyl group having 4 to 25 carbon atoms, a linear alkenyl group having 2 to 25 carbon atoms, or a branched alkenyl group having 4 to 25 carbon atoms.

2. The nanoparticle according to claim 1, wherein the attaching group is represented by following chemical formula (I′),
M(O₂CR¹)₂ (I′)
wherein R¹ is a linear alkyl group having 1 to 15 carbon atoms, preferably 1 to 10 carbon atoms, more preferably 1 to 8 carbon atoms, even more preferably 1 to 4 carbon atoms, further more preferably 1 to 2 carbon atoms, or an alkenyl group having 2 to 15 carbon atoms, preferably 2 to 10 carbon atoms, more preferably 2 to 6 carbon atoms, even more preferably 2 to 4 carbon atoms.

3. The nanoparticle according to claim 1, wherein the attaching group is Zn²⁺(CH₃COO⁻)₂.

4. A semiconducting light emitting nanoparticle comprising or consisting of a core, one or more shell layers, a 1^{st} attaching group and a 2^{nd} attaching group placed onto the outermost surface of the shell layers, wherein said 1^{st} attaching group is represented by following chemical formula (II), and said 2^{nd} attaching group is represented by following chemical formula (III),
[M(O₂CR⁵)⁻]⁺ (II)
O₂CR⁶⁻ (III)
wherein M is Zn²⁺ or Cd²⁺, preferably M is Zn²⁺,
R⁵ is a linear alkyl group having 1 to 15 carbon atoms, a branched alkyl group having 4 to 15 carbon atoms, a linear alkenyl group having 2 to 15 carbon atoms, or a branched alkenyl group having 4 to 15 carbon atoms, preferably R⁵ is a linear alkyl group having 1 to 15 carbon atoms or a linear alkenyl group having 2 to 15 carbon atoms, more preferably R⁵ is a linear alkyl group having 1 to 10 carbon atoms or a linear alkenyl group having 2 to 10 carbon atoms, even more preferably R⁵ is a linear alkyl group having 1 to 8 carbon atoms or a linear alkenyl group having 2 to 6 carbon atoms, further more preferably R⁵ is a linear alkyl group having 1 to 4 carbon atoms or a linear alkenyl group having 2 to 4 carbon atoms, the most preferably R⁵ is a linear alkyl group having 1 to 2 carbon atoms,
R⁶ is a linear alkyl group having 1 to 15 carbon atoms, a branched alkyl group having 4 to 15 carbon atoms, a linear alkenyl group having 2 to 15 carbon atoms, or a branched alkenyl group having 4 to 15 carbon atoms, preferably R⁶ is a linear alkyl group having 1 to 15 carbon atoms or a linear alkenyl group having 2 to 15 carbon atoms, more preferably R⁶ is a linear alkyl group having 1 to 10 carbon atoms or a linear alkenyl group having 2 to 10 carbon atoms, even more preferably R⁶ is a linear alkyl group having 1 to 8 carbon atoms or a linear alkenyl group having 2 to 6 carbon atoms, further more preferably R⁶ is a linear alkyl group having 1 to 4 carbon atoms or a linear alkenyl group having 2 to 4 carbon atoms, the most preferably R⁶ is a linear alkyl group having 1 to 2 carbon atoms.

5. The nanoparticle according to claim 1, wherein at least one of the shell layers comprises a 1^{st} element of group 12 of the periodic table, preferably the 1^{St} element is Zn or Cd,
and a 2^{nd} element of group 16 of the periodic table, preferably the 2^{nd} element is S, Se, or Te.

6. The nanoparticle according to claim 1, wherein at least one shell layer is represented by following formula (IV),
ZnSₓSe_{y}Te_{z}, (IV)
wherein 0≤x≤1, 0≤y≤1, 0≤z≤1, and x+y+z=1, preferably 0≤x≤1, 0≤y≤1, z=0, and x+y=1.

7. The nanoparticle according to claim 1, wherein said shell layers of the semiconducting light emitting nanoparticle are double shell layers

8. The nanoparticle according to claim 1, wherein the core comprises In and P atoms.

9. A process for fabricating a semiconducting light emitting nanoparticle, wherein the method comprises or consists of the following step (a),
(a) providing the attaching group represented by chemical formula (I) and a semiconducting light emitting nanoparticle comprising a core, one or more shell layers into a solvent to get a mixture.

10. A process for preparing a semiconducting light emitting nanoparticle, wherein the process comprises or consists of following steps (a′) and (b) in this sequence,
(a′) preparing a semiconducting light emitting nanoparticle comprising a core, one or more shell layers and an attaching group placed onto the outermost surface of the shell layers, wherein the attaching group is represented by following chemical formula (V),
MYXZ (V)
wherein M is a divalent metal ion, preferably M is Zn²⁺, Cd²⁺, more preferably it is Zn²⁺;
Y and X are, independently or differently of each other, selected from the group consisting of carboxylates, halogens, acetylacetonates, phosphates, phosphonates, sulfonates, sulfates, thiocarbamates, dithiocarbamates, thiolates, dithiolates and alkoxylates, preferably, Y and X are identical,
Z is (NR⁷R⁸R⁹)_{y}
wherein y is 0, or 2, preferably y is 0,
R⁷, R⁸ and R⁹ are independently or dependently of each other, selected from the group consisting of a hydrogen atom, a linear alkyl group having 1 to 25 carbon atoms, a branched alkyl group having 4 to 25 carbon atoms, a linear alkenyl group having 2 to 25 carbon atoms, and a branched alkenyl group having 4 to 25 carbon atoms,
with the proviso that at least one of R⁷, R⁸ and R⁹ is a linear alkyl group having 1 to 25 carbon atoms, a branched alkyl group having 4 to 25 carbon atoms, a linear alkenyl group having 2 to 25 carbon atoms, or a branched alkenyl group having 4 to 25 carbon atoms,
(b) Irradiating light with a peak light wavelength in the range from 300 nm to 650 nm to the semiconducting light emitting nanoparticle, with preferably being in the range from 320 nm to 520 nm, more preferably from 350 nm to 500 nm, even more preferably at 360 nm to 470 nm.

11. The process according to claim 10, wherein a light source for light irradiation in step (b) is selected from one or more of artificial light sources, preferably selected from a light emitting diode, an organic light emitting diode, a cold cathode fluorescent lamp, or a laser device.

12. The process according to claim 10, wherein the attaching group is a carboxylate represented by following chemical formula (VI),
[M(O₂CR¹⁰)(O₂CR¹¹)] (VI)
wherein M is Zn²⁺ or Cd²⁺, preferably M is Zn²⁺,
wherein R¹⁰ is a linear alkyl group having 1 to 25 carbon atoms, a branched alkyl group having 4 to 25 carbon atoms, a linear alkenyl group having 2 to 25 carbon atoms, or a branched alkenyl group having 4 to 25 carbon atoms, preferably R¹⁰ is a linear alkyl group having 1 to 25 carbon atoms, or a linear alkenyl group having 2 to 25 carbon atoms, more preferably R¹⁰ is a linear alkyl group having 1 to 20 carbon atoms, or a linear alkenyl group having 2 to 20 carbon atoms,
R¹¹ is a linear alkyl group having 1 to 25 carbon atoms, a branched alkyl group having 4 to 25 carbon atoms, a linear alkenyl group having 2 to 25 carbon atoms, or a branched alkenyl group having 4 to 25 carbon atoms, preferably R¹¹ is a linear alkyl group having 1 to 25 carbon atoms, or a linear alkenyl group having 2 to 25 carbon atoms, more preferably R¹¹ is a linear alkyl group having 1 to 20 carbon atoms, or a linear alkenyl group having 2 to 20 carbon atoms,

13. The process according to claim 10, wherein the intention of the light irradiation is in the range from 0.025 to 1 watt/cm², preferably it is in the range from 0.05 to 0.5 watt/cm².

14. A semiconducting light emitting nanoparticle obtainable or obtained from the process according to claim 9.

15. A composition comprising the semiconducting light emitting nanoparticle according to claim 1,
and at least one additional material, preferably the additional material is selected from the group consisting of organic light emitting materials, inorganic light emitting materials, charge transporting materials, scattering particles, and matrix materials, preferably the matrix materials are optically transparent polymers.

16. A formulation comprising the semiconducting light emitting nanoparticle according to claim 1,
and at least one solvent, preferably the solvent is selected from one or more members of the group consisting of aromatic, halogenated and aliphatic hydrocarbons solvents, more preferably selected from one or more members of the group consisting of toluene, xylene, ethers, tetrahydrofuran, chloroform, dichloromethane and heptane.

17. A method comprising including a semiconducting light emitting nanoparticle according to claim 1 in an electronic device, optical device or in a biomedical device.

18. An optical medium comprising said semiconducting light emitting nanoparticle according to claim 1.

19. An optical device comprising said optical medium according to claim 18.
